(19) United States
(12) Patent Application Publication
(10) Pub. No.: US 2024/0248391 A1
(43) Pub. Date: Jul. 25, 2024

(54) EXTREME ULTRAVIOLET PELLICLES AND METHOD OF MANUFACTURING

(71) Applicant: Applied Mateials, Inc., Santa Clara, CA (US)

(72) Inventors: Thomas Joseph Knisley, Livonia, MI (US); Lakmal C. Kalutarage, San Jose, CA (US); Mark Saly, Santa Clara, CA (US); Nasrin Kazem, Santa Clara, CA (US); Feng Q. Liu, San Jose, CA (US); Jeffrey W. Anthis, San Jose, CA (US)

(73) Assignee: Applied Mateials, Inc., Santa Clara, CA (US)

(21) Appl. No.: 18/413,484

(22) Filed: Jan. 16, 2024

Related U.S. Application Data
(60) Provisional application No. 63/440,172, filed on Jan. 20, 2023.

(51) Int. Cl. G03F 1/62

(52) U.S. Cl. CPC G03F 1/62

(57) ABSTRACT

Methods of manufacturing an extreme ultraviolet (EUV) pellicles are disclosed. The methods comprise forming on a carbon nanotube (CNT) membrane of an EUV pellicle a nucleation layer. A protective material layer is deposited on the nucleation layer, the protective material layer exhibiting greater than 90% transmission of 13.5 nm EUV light. The methods may be performed by atomic layer deposition. The protective material layer may be selected from aluminum (Al), aluminum nitride (AlN), aluminum oxide (Al₂O₃), boron carbide (B₄C), boron nitride (BN), molybdenum (Mo), molybdenum silicide (MoSi₂), molybdenum carbide (MoC, Mo₂C), ruthenium (Ru), ruthenium niobium alloy (RuNb), ruthenium oxide (RuO, RUO₂), tantalum nitride (TaN), tantalum (Ta), yttrium nitride (YN), zirconium boride (ZrB₂), zirconium silicide (ZrSi₂), and silicon carbide (SiC).

### CROSS-REFERENCE TO RELATED APPLICATIONS

The present disclosure claims priority to U.S. provisional patent application Ser. No. 63/440,172 filed on Jan. 20, 2023, the entire content of which is incorporated herein by reference.

### TECHNICAL FIELD

The present disclosure relates generally to processing of thin substrates, and more particularly to processing thin substrates used in semiconductor processing such as pellicles used to manufacture extreme ultraviolet mask blanks.

### BACKGROUND

In extreme ultraviolet (EUV) lithography (EUVL), which can be used for the manufacture of 0.0135 micron and smaller minimum feature size semiconductor devices, a thin pellicle is used during manufacture of integrated circuits. More specifically, in EUVL a photomask, e.g., a reticle, may be repeatedly used to reproducibly print thousands of substrates to form integrated circuits. Typically, a reticle is a glass or a quartz substrate including a film stack having multiple layers, including a light-absorbing layer and an opaque layer disposed thereon. A pellicle is used to protect the reticle from particle contamination by mounting the pellicle a few millimeters above the photomask surface, mechanically separating particles from the photomask surface. A pellicle is a thin transparent membrane which allows light and radiation to pass therethrough to the reticle and which is stretched above and not touching the surface of the mask.

A key feature of an EUV pellicle is that the pellicle permits transmission of EUV light to ensure the productivity of the EUV lithography system, for example, at least 90% transmission of EUV light (e.g., at the 13.5 nm exposure wavelength). Low transmission reduces the effective exposure power and thwarts productivity of the EUVL system. The pellicle also needs to be mechanically stable, which is difficult to achieve for membranes that are thin enough to meet EUV transmission requirements. The thin membrane is mounted on a frame and fixed to the photomask. Pellicles comprising carbon nanotube (CNT) membranes have been used in EUVL, but CNT-based pellicles have not been able to survive EUV exposures. Accordingly, there is a need for EUV pellicles comprising a CNT membrane that can survive multiple prolonged EUV exposures.

### SUMMARY

One or more embodiments of the disclosure are directed to a method of manufacturing an extreme ultraviolet (EUV) pellicle, the method comprising forming on a carbon nanotube (CNT) membrane of an EUV pellicle a nucleation layer; and depositing a protective material layer on the nucleation layer, the protective material layer exhibiting greater than 90% transmission of 13.5 nm EUV light.

Another embodiment pertains to method of manufacturing an extreme ultraviolet (EUV) pellicle, the method comprising forming on a carbon nanotube (CNT) membrane of an EUV pellicle a nucleation layer using an atomic layer deposition process including sequentially exposing the CNT membrane to an oxygen-containing gas, a purge gas, trimethlyaluminum vapor and a purge gas; and depositing a protective material layer on the nucleation layer, the protective material layer exhibiting greater than 90% transmission of 13.5 nm EUV light.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A is a schematic isometric view of an exemplary photomask assembly, according to one embodiment;

FIG. 1B is a cross-sectional view of the photomask assembly shown in FIG. 1A taken along line 1B-1B;

FIG. 2 schematically illustrates an embodiment of an extreme ultraviolet lithography system;

FIG. 3 is a flow chart illustrating an embodiment of a method.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “horizontal” as used herein is defined as a plane parallel to the plane or surface of a mask blank, regardless of its orientation. The term “vertical” refers to a direction perpendicular to the horizontal as just defined. Terms, such as “above”, “below”, “bottom”, “top”, “side”, “higher”, “lower”, “upper”, “over”, and “under”, are defined with respect to the horizontal plane, as shown in the figures. The term “on” indicates that there is contact between elements, which can include intervening elements. The term “directly on” indicates that there is direct contact between elements with no intervening elements.

As used in this specification and the appended claims, the terms “precursor”, “reactant”, “reactive gas” and the like are used interchangeably to refer to any gaseous species that can react with the substrate surface.

Those skilled in the art will understand that the use of ordinals such as “first” and “second” to describe process regions do not imply a specific location within the processing chamber, or order of exposure within the processing chamber.

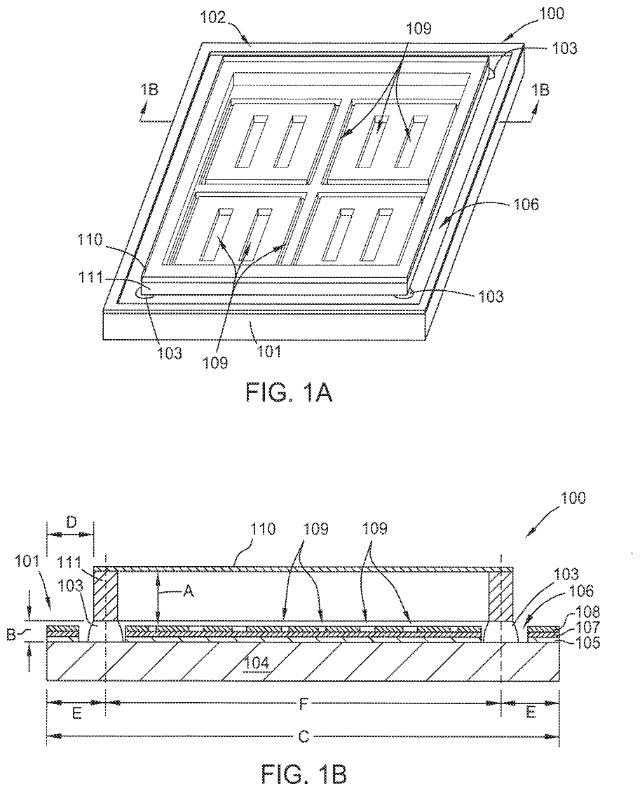

FIG. 1A is a schematic isometric view of an exemplary lithography mask assembly, according to one embodiment. FIG. 1B is a schematic cross-sectional view of the lithography mask assembly in FIG. 1A taken along line 1B-1B. Typically, the lithography mask assembly 100 includes an lithography photomask 101 and an EUV pellicle 102 secured thereto by a plurality of adhesive patches 103 interposed therebetween. In some embodiments the lithography photomask 101 is configured for use with an extreme ultraviolet (EUV) lithography processing system and features a substrate 104, a reflective multilayer stack 105 disposed on the substrate 104, a capping layer 107 disposed on the reflective multilayer stack 105, and an absorber layer 108 disposed on the capping layer 107. In some embodiments, the substrate 104 comprises a low thermal expansion material (LTEM), such as a titanium doped fused silica. In some embodiments, the reflective multilayer stack 105 comprises a plurality of repeating material and silicon layers, such as a plurality of repeating Mo and Si layers, i.e., a plurality of Mo/Si layers. In some embodiments, the reflective multilayer stack 105 comprises more than about 40 alternating layers of material and silicon and has a thickness in a range from 200 nm to 250 nm. In some embodiments, the absorber layer 108 is formed of a material comprising tantalum (Ta), such as a TaBO layer, a TaBN layer, or multilayer stack thereof, for example a TaBO layer disposed on a TaBN layer. In other embodiments, the absorber layer comprises an alloy of materials selected from the group consisting of platinum (Pt), zinc (Zn), gold (Au), nickel oxide (NiO), silver oxide (Ag₂O), iridium (Ir), iron (Fe), tin dioxide (SnO₂), cobalt (Co), chromium nickel alloys, copper (Cu), silver (Ag), actinium (Ac), tellurium (Te), caesium iodide (CsI), tin (Sn), zinc telluride (ZnTe), antimony (Sb), tantalum (Ta), chromium (Cr), and chromium nitride (CrN). In some embodiments, the absorber layer 108 has a thickness in a range of from 10 nm to 80 nm or in a range of from 10 nm to 45 nm. In some embodiments, the capping layer 107 is formed of ruthenium (Ru) and has a thickness in a range from 1 nm to 5 nm, for example, about 2.5 nm.

The absorber layer 108, having a plurality of openings 109 formed therethrough, forms a patterned surface of the lithography photomask 101. Here, individual ones of the openings 109 extend through the absorber layer 108 to expose the capping layer 107 disposed therebeneath. In other embodiments, individual ones of the openings 109 further extend through the capping layer 107 to expose the reflective multilayer stack 105 disposed therebeneath. In some embodiments, the lithography photomask 101 comprises one or more black-border openings 106, i.e., one or more openings extending through the absorber layer 108, the capping layer 107, and the reflective multilayer stack 105.

In one or more embodiments, the EUV pellicle 102 includes a thin (e.g., <200 nm in thickness) CNT membrane 110, extending across a pellicle frame 111 and secured thereto by an adhesive layer (not shown) interposed therebetween. The CNT membrane 110 is spaced apart from the surface of the lithography photomask 101 by a distance A. The pellicle frame 111 is spaced apart from the surface of the lithography photomask 101 by a thickness of the adhesive patches 103, for example, a distance B of less than about 1 mm, such as between about 10 μm and about 500 μm. The adhesive patches 103 are disposed directly on the surface of the substrate 104. In other embodiments, the adhesive patches 103 are disposed directly on the surface of the reflective multilayer stack 105. In other embodiments, the adhesive patches 103 are disposed directly on the surface of the absorber layer 108.

Spacing of the CNT membrane 110 from the surface of the lithography photomask 101 desirably prevents particles, e.g., dust, which become collected thereon from being in the field of focus when the lithography mask pattern is transferred to a resist layer on a workpiece. Spacing the pellicle frame 111 from the surface of the lithography photomask 101 desirably allows clean gas, e.g., air, to flow between the EUV pellicle 102 and the lithography photomask 101. The free flow of gas between the EUV pellicle 102 and the lithography photomask 101 desirably prevents unequal pressures on the opposite surface of the membrane during a vacuum EUV lithography process which could cause the fragile CNT membrane 110 to rupture. In embodiments herein, the adhesive patches 103 used to secure the EUV pellicle 102 to the surface of the lithography photomask 101 are disposed in patches at a discrete plurality of locations, such as proximate to the corners of the pellicle frame 111. For example, in some embodiments the lithography mask has a square shape in cross section where each side of the lithography mask has a length C of between about 100 mm and about 300 mm, for example about 150 mm. The sides of the pellicle frame 111 are disposed inwardly of the sides of the lithography photomask 101 by a distance D of between about 0 mm and about 30 mm when measured at angles orthogonal thereto. The plurality of adhesive patches 103 are disposed at the corners of the frame and have a center to center spacing F between about 70 mm and about 140 mm. The center of the adhesive patches are at a distance E from each side of the lithography mask. Other arrangements of the adhesive are within the scope of the disclosure, and the foregoing description is exemplary only.

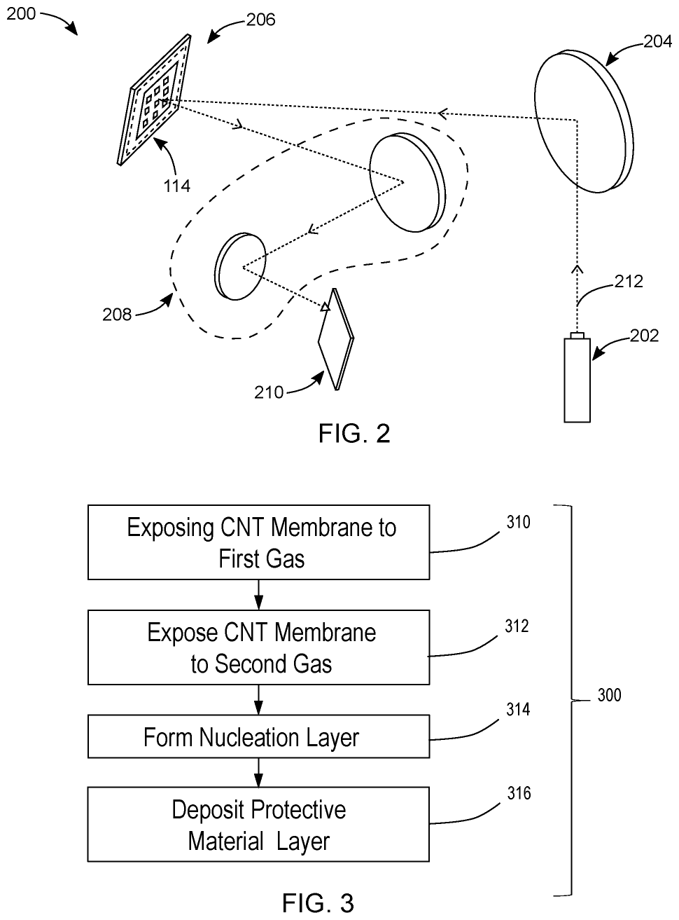

Referring now to FIG. 2, an exemplary embodiment of an extreme ultraviolet lithography system 200 (or EUVL system, EUVL tool or EUVL scanner) is shown. The extreme ultraviolet lithography system 200 includes an extreme ultraviolet light source 202 for producing extreme ultraviolet light 212, a set of reflective elements, and a target wafer 210. The reflective elements include a condenser 204, an EUV reflective photomask 206, an optical reduction assembly 208, a mask blank, a mirror, or a combination thereof.

The extreme ultraviolet light source 202 generates the extreme ultraviolet light 212. The extreme ultraviolet light 212 is electromagnetic radiation having a wavelength in a range of 5 to 50 nanometers (nm). For example, the extreme ultraviolet light source 202 includes a laser, a laser produced plasma, a discharge produced plasma, a free-electron laser, synchrotron radiation, or a combination thereof. In one or more embodiments, the extreme ultraviolet light source 202 produces the extreme ultraviolet light 212 having a narrow bandwidth. For example, the extreme ultraviolet light source 202 generates the extreme ultraviolet light 212 at 13.5 nm. The center of the wavelength peak is 13.5 nm.

The condenser 204 reflects and concentrates the extreme ultraviolet light 212 from the extreme ultraviolet light source 202 to illuminate the EUV reflective photomask 206. Although the condenser 204 is shown as a single element, it is understood that the condenser 204 in some embodiments includes one or more reflective elements such as concave mirrors, convex mirrors, flat mirrors, or a combination thereof, for reflecting and concentrating the extreme ultraviolet light 212. For example, the condenser 204 in some embodiments is a single concave mirror or an optical assembly having convex, concave, and flat optical elements.

The EUV reflective photomask has a mask pattern 214 which creates a lithographic pattern to form a circuitry layout to be formed on the target wafer 210. The EUV reflective photomask 206 reflects the extreme ultraviolet light 212, and the mask pattern 214 defines a portion of a circuitry layout to semiconductor device.

The optical reduction assembly 208 is an optical unit for reducing the image of the mask pattern 214. The reflection of the extreme ultraviolet light 212 from the EUV reflective photomask 206 is reduced by the optical reduction assembly 208 and reflected on to the target wafer 210. The optical reduction assembly 208 in some embodiments includes mirrors and other optical elements to reduce the size of the image of the mask pattern 114. For example, the optical reduction assembly 208 in some embodiments includes concave mirrors for reflecting and focusing the extreme ultraviolet light 212.

The optical reduction assembly 208 reduces the size of the image of the mask pattern 214 on the target wafer 210. For example, the mask pattern 214 in some embodiments is imaged at a 4:1 ratio by the optical reduction assembly 208 on the target wafer 210 to form the circuitry represented by the mask pattern 214 on the target wafer 210. The extreme ultraviolet light 212 in some embodiments scans the EUV reflective photomask 206 synchronously with the target wafer 210 to form the mask pattern 214 on the target wafer 210. While not shown in FIG. 2, the EUV pellicle described with respect to FIG. 1A and FIG. 1B protects the photomask 206 from contamination.

It was discovered that EUV pellicles comprising a CNT membrane cannot survive multiple prolonged EUV exposures in an EUVL tool or scanner. This limits the lifetime of the EUV pellicle in the scanner, which can lead to unexpected chamber contamination in the form of CNT fragments and EUV scanner downtime for an EUV pellicle replacement. Applicant has discovered an EUV pellicle comprising a protective coating that does not interfere with EUV photons (reflection, absorption), which will one significantly extend the lifetime of EUV pellicle comprising a CNT membrane.

In one or more embodiments, the protective coating, for example, a protective material coating is deposited by cyclical deposition (or cyclical layer deposition (CLD)) or atomic layer deposition (ALD) in a substrate processing chamber configured to achieve the particular type of deposition process. It was further discovered that due to the inherently inert nature of carbon nanotubes, deposition of a protective material coating proved to be a difficult and challenging process. Initial experiments resulted in the CNT membrane of the EUV pellicle during the material layer formation process.

Furthermore, upon coating of the CNT membrane 110, the EUV pellicle of one or more embodiments exhibits EUV transmission of EUV light at 13.5 nm exceeding 90%, 91%, 92%, 93%, 94%, 95%, 96% or 97%. The protective coating of one or more embodiments does not degrade transmission of EUV light through the EUV pellicle at 13.5 nm more than 3% compared to an uncoated EUV pellicle. The protective coating of some embodiments provides high resistance to hydrogen plasma to protect the CNT membrane from EUV-active and EUV chamber cleaning processes. The coating of one or more embodiments remains pliable and reduces sag of the CNT membrane. According to some embodiments, the protective coated CNT membrane survives temperatures exceeding 1200° C., and the protective coating enhances emissivity of the CNT membrane. Emissivity at EUV wavelengths such as 13.5 nm refers to the ability of the CNT membrane to withstand a rapid heating and cooling process in the EUV lithography system. In one or more embodiments, the protective coating is conformal, and the protective coating minimizes process-induced damage to the CNT membrane.

“Atomic layer deposition” or “cyclical deposition” as used herein refers to the sequential exposure of two or more reactive compounds to deposit a layer of material on a CNT membrane 110. The CNT membrane 110, or a portion of the CNT membrane 110, is exposed separately to the two or more reactive compounds which are introduced into a reaction zone of a processing chamber. In a time-domain ALD process, exposure to each reactive compound is separated by a time delay to allow each compound to adhere and/or react on the CNT membrane 110 and then be purged from the processing chamber. These reactive compounds are said to be exposed to the CNT membrane 110 sequentially. In a spatial ALD process, different portions of the CNT membrane 110, or material on the CNT membrane, are exposed simultaneously to the two or more reactive compounds so that any given point on the CNT membrane 110 is substantially not exposed to more than one reactive compound simultaneously. As used in this specification and the appended claims, the term “substantially” used in this respect means, as will be understood by those skilled in the art, that there is the possibility that a small portion of the CNT membrane 110 may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired layer thickness is formed on the CNT membrane 110. In either scenario, the ALD process of pulsing compound A (e.g., an oxygen-containing gas such as N₂O), purge gas, compound B (e.g., a group 13-16 alkyl precursor such as trimethylaluminum) and purge gas (e.g., an inert gas such as argon or nitrogen) is a cycle. A cycle can start with either compound A or compound B and continue the respective order of the cycle until achieving a layer with the predetermined thickness. In the case of forming a nucleation layer as described herein, the process can comprise as few as one cycle, so long as the exposure of the CNT membrane 110 of the EUV pellicle 102 to the group 13-16 alkyl precursor provides an alkyl group extending from the CNT membrane 110 to cause the protective material layer to adhere to the CNT membrane.

In an embodiment of a spatial ALD process, a first reactive gas (e.g., an oxygen-containing gas) and second reactive gas (e.g., trimethylaluminum vapor) are delivered simultaneously to the reaction zone but are separated by an inert gas curtain and/or a vacuum curtain. The CNT membrane 110 is moved relative to the gas delivery apparatus so that any given point on the CNT membrane 110 is exposed to the first reactive gas and the second reactive gas to form a nucleation layer the facilitates adherence of a protective material layer. The protective material layer can be formed by any suitable process, including chemical vapor deposition, cyclical deposition, atomic layer deposition and physical vapor deposition.

Thus, according to an embodiment, a method of manufacturing an extreme ultraviolet (EUV) pellicle comprises forming on a carbon nanotube (CNT) membrane of the EUV pellicle a nucleation layer using an atomic layer deposition process including sequentially exposing the CNT membrane to oxygen-containing gas pulse, a purge gas pulse, a group 13-16 alkyl precursor pulse and a purge gas pulse. Then, the method includes depositing a protective material layer on the nucleation layer, the protective material layer exhibiting greater than 90% transmission of 13.5 nm EUV light. Examples of oxygen-containing gases include NO₂, N₂O, CO, CO₂, ozone, oxygen, volatile peroxides/hydroperoxides (e.g., hydrogen peroxide (H₂O₂), and volatile organic acids (e.g., formic acid and acetic acid). The oxygen-containing gas can be flowed as a pulse of the gas that in some embodiments is mixed with an inactive or inert gas, for example, nitrogen, argon or mixtures thereof. Exposing the CNT membrane to oxygen-containing gas results in the CNT membrane having reactive oxygen on a surface of the CNT membrane. In specific embodiments, the oxygen-containing gas pulse is selected from one or more of NO₂, N₂O, CO and CO₂. Non-limiting examples of group 13-16 alkyl precursors include alkyl (e.g., methyl, ethyl, propyl, butyl) precursors including an element from groups 13-16 of the Periodic Table such as boron, aluminum, gallium, indium, germanim, tin, and selenium. In specific embodiments, non-limiting alkyl precursors are selected from the group consisting of trimethylaluminum, triethylaluminum, trimethylgallium, triethylgallium trimethylindium, tetramethyltin, tetra-n-propyl tin, triethylboron, trimethylindium, trimethyl germanium, triethylgermanium, diethyldiselenide, dimethylselenide, trimethyl germanium, and triethylgermanium. Exposing the CNT membrane to the group 13-16 alkyl precursor results in the CNT membrane having a reactive alkyl (e.g., methyl or ethyl) on the surface of the CNT membrane.

In one or more embodiments, the CNT membrane comprises at least one sheet of carbon nanotube bundles. In one or more embodiments, a carbon nanotube bundle comprises individual carbon nanotubes aligned along a predominant direction to form bundles. In some embodiments, the individual carbon nanotubes comprise or consist of single-walled carbon nanotubes. In some embodiments, the individual nanotubes comprise or consist of multi-walled carbon nanotubes. Such carbon nanotube bundles can form spontaneously during manufacture of carbon nanotube sheets or membranes, such as those available from Canatu, Vantaa, Finland. The carbon nanotube membrane may contain up to 1 atomic percent iron, which may comprise nanoparticles of iron.

Referring to FIG. 3 and exemplary method 300 of manufacturing an extreme ultraviolet (EUV) pellicle includes at 310 exposing the CNT membrane to a first gas and exposing the CNT membrane to a gas at 312 to form a nucleation layer at 314. Next, a protective material layer is deposited on the CNT membrane, which bonds to the nucleation layer. It was determined that the nucleation layer formation was instrumental in forming a protective layer that met one or more of the requirements described herein. For example, the protective material layer on the nucleation layer exhibits greater than 90% transmission of 13.5 nm EUV light. In some embodiments, the EUV pellicle exhibits greater than 91%, 92%, 93%, 94%, 95%, 96% or 97%. The protective coating of one or more embodiments does not degrade transmission of EUV light through the EUV pellicle at 13.5 nm more than 3% compared to an uncoated EUV pellicle. The protective coating of some embodiments provides high resistance to hydrogen plasma to protect the CNT membrane from EUV-active and EUV chamber cleaning processes. The coating of one or more embodiments remains pliable and reduces sag of the CNT membrane. According to some embodiments, the protective coated CNT membrane survives temperatures exceeding 1200° C., and the protective coating enhances emissivity of the CNT membrane. Emissivity at EUV wavelengths such as 13.5 nm refers to the ability of the CNT membrane to withstand a rapid heating and cooling process in the EUV lithography system. In one or more embodiments, the protective coating is conformal, and the protective coating minimizes process-induced damage to the CNT membrane.

In some embodiments, forming the nucleation layer comprises an atomic layer deposition process. In one embodiment, forming the nucleation layer comprises exposing the CNT membrane to oxygen-containing gas. Then, the method further comprises exposing the CNT membrane to a group 13-16 alkyl precursor after exposing the CNT to the oxygen-containing gas. According to some embodiments, exposing the CNT membrane to a group 13-16 alkyl precursor forms a reactive methyl group extending from the CNT membrane.

An exemplary ALD process further comprises exposing the CNT membrane to a purge gas after exposing the CNT membrane to the NO₂ gas and prior to exposing the CNT membrane to the group 13-16 alkyl precursor. In further embodiments, the method comprises repeating exposing the CNT membrane to the oxygen-containing gas, the purge gas and the group 13-16 alkyl precursor. The method may involve repeating the process any number of times.

The protective material layer according to one or more embodiments comprises a material selected from the group consisting of molybdenum (Al), aluminum nitride (AlN), aluminum oxide (Al₂O₃), boron carbide (B₄C), boron nitride (BN), molybdenum (Mo), molybdenum silicide (MoSi₂), molybdenum carbide (MoC, Mo₂C), ruthenium (Ru), ruthenium niobium alloy (RuNb), ruthenium oxide (RuO, RUO₂), tantalum nitride (TaN), tantalum (Ta), yttrium nitride (YN), zirconium boride (ZrB₂), zirconium silicide (ZrSi₂), and silicon carbide (SiC). Each of the aforementioned coatings have high transmission at 13.5 nm. Materials with low emissivity are also desired, so that the EUV pellicle is able to withstand fast heating and cooling processes encountered in an system or tool or scanner as shown in FIG. 2.

In specific embodiments, a Mo coating having a thickness of less than 4 nm provides high transmission and low emissivity at 13.5 nm. A B₄C having a thickness of less than 4 nm provides high transmission and low emissivity at 13.5 nm. A BN coating having a thickness of less than 3 nm provides high transmission and low emissivity at 13.5 nm. A MoSi coating having a thickness of less than 3 nm provides high transmission and low emissivity at 13.5 nm. A SiN coating having a thickness of less than 2 nm provides high transmission and low emissivity at 13.5 nm. A Ru coating having a thickness of less than 2 nm provides high transmission and low emissivity at 13.5 nm. A MoC coating having a thickness of less than 4 nm provides high transmission and low emissivity at 13.5 nm. Each of these coatings has a minimum thickness of 0.1 nm. In some embodiments, a monolayer of Al₂O₃ can be utilized. In addition, each of these coatings provides protection to the CNT membrane during EUV processes.

In an exemplary ALD process to form the nucleation layer, the CNT membrane is first exposed to the oxygen-containing gas pulse for 1 to 60 seconds, 1 to 30 seconds, 1 to 20 seconds or 1 to 10 seconds. The pressure during the oxygen-containing gas pulse exposure is in a range from 1 to 20 Torr, 1 to 15 Torr or 1 to 10 Torr. Flow rates of the oxygen-containing gas pulse into a substrate processing chamber of 1 to 1000 SCCm, 1 to 500 SCCm or 1 to 300 SCCm are used. Next a purge gas exposure is from 1 to 60 seconds or 1 to 30 seconds. Exposure to the group 13-16 alkyl precursor pulse is in a range of 0.01 to 60 seconds, 0.01 to 30 seconds or 0.01 to 10 seconds. The pressure during exposure to the group 13-16 alkyl precursor pulse is in a range of 1 to 2000 Torr, 1 to 1500 Torr or 1 to 1000 Torr. In one or more embodiments, the temperature in the processing chamber during atomic layer deposition is in a range from 25° C. to 400° C., for example 50° C. to 200° C.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method of manufacturing an extreme ultraviolet (EUV) pellicle including a carbon nanotube (CNT) membrane, the method comprising:
forming a nucleation layer on the CNT membrane; and
depositing a protective material layer on the nucleation layer, the protective material layer exhibiting greater than 90% transmission of 13.5 nm EUV light.

2. The method of claim 1, wherein forming the nucleation layer comprises an atomic layer deposition process.

3. The method of claim 2, wherein forming the nucleation layer comprises exposing the CNT membrane to an oxygen-containing gas.

4. The method of claim 3, further comprising exposing the CNT membrane to a group 13-16 alkyl precursor after exposing the CNT to the oxygen-containing gas.

5. The method of claim 4, wherein exposing the CNT membrane to the group 13-16 alkyl precursor forms a reactive methyl group extending from the CNT membrane.

6. The method of claim 4, further comprising exposing the CNT membrane to a purge gas after exposing the CNT membrane to the oxygen-containing gas and prior to exposing the CNT membrane to the group 13-16 alkyl precursor.

7. The method of claim 6, further comprising repeatedly exposing the CNT membrane to the oxygen-containing gas, the purge gas and the group 13-16 alkyl precursor.

8. The method of claim 6, wherein the protective material layer comprises a material selected from the group consisting of aluminum (Al), aluminum nitride (AlN), aluminum oxide (Al₂O₃), boron carbide (B₄C), boron nitride (BN), molybdenum (Mo), molybdenum silicide (MoSi₂), molybdenum carbide (MoC, Mo₂C), ruthenium (Ru), ruthenium niobium alloy (RuNb), ruthenium oxide (RuO, RUO₂), tantalum nitride (TaN), tantalum (Ta), yttrium nitride (YN), zirconium boride (ZrB₂), zirconium silicide (ZrSi₂), and silicon carbide (SiC).

9. The method of claim 6, wherein the protective material layer comprises Ru having a thickness of less than 2 nm and greater than 0.1 nm.

10. The method of claim 6, wherein the protective material layer comprises SiN having a thickness of less than 3 nm and greater than 0.1 nm.

11. The method of claim 6, wherein the CNT membrane is exposed to the oxygen-containing gas for 1 to 60 seconds at a pressure in a range from 1 to 20 Torr.

12. The method of claim 10, wherein the CNT membrane is exposed to the group 13-16 alkyl precursor for 0.01 to 60 seconds and at a pressure from 1 to 2000 Torr.

13. The method of claim 11, wherein the CNT membrane is exposed to the purge gas for 1 to 60 seconds.

14. The method of claim 7, wherein the CNT membrane comprises a sheet of carbon nanotube bundles comprising a plurality of substantially parallel carbon nanotube bundles.

15. The method of claim 7, wherein the CNT membrane comprises a sheet of carbon nanotube bundles comprising single-walled carbon nanotubes.

16. The method of claim 7, wherein the CNT membrane comprises a sheet of carbon nanotube bundles comprising multi-walled carbon nanotubes.

17. A method of manufacturing an extreme ultraviolet (EUV) pellicle including a carbon nanotube (CNT) membrane, the method comprising:
forming a nucleation layer on the CNT membrane using an atomic layer deposition process including sequentially exposing the CNT membrane to an oxygen-containing gas, a purge gas, trimethlyaluminum vapor and a purge gas; and
depositing a protective material layer on the nucleation layer, the protective material layer exhibiting greater than 90% transmission of 13.5 nm EUV light.

18. The method of claim 17, wherein the protective material layer comprises a material selected from the group consisting of aluminum (Al), aluminum nitride (AlN), aluminum oxide (Al₂O₃), boron carbide (B₄C), boron nitride (BN), molybdenum (Mo), molybdenum silicide (MoSi₂), molybdenum carbide (MoC, Mo₂C), ruthenium (Ru), ruthenium niobium alloy (RuNb), ruthenium oxide (RuO, RUO₂), tantalum nitride (TaN), tantalum (Ta), yttrium nitride (YN), zirconium boride (ZrB₂), zirconium silicide (ZrSi₂), and silicon carbide (SiC).

19. The method of claim 18, wherein the protective material layer comprises Ru having a thickness of less than 2 nm and greater than 0.1 nm.

20. The method of claim 18, wherein the protective material layer comprises SiN having a thickness of less than 3 nm and greater than 0.1 nm.
